(19) United States
(12) Patent Application Publication
(10) Pub. No.: US 2017/0062656 A1
(43) Pub. Date: Mar. 2, 2017

(54) LED ELEMENT WITH PROTECTING LAYER

(71) Applicant: ADVANCED OPTOELECTRONIC TECHNOLOGY, INC., Hsinchu Hsien 303 (TW)

(72) Inventors: TZU-CHIEN HUNG, Hukou (TW); YA-CHI LIEN, Hukou (TW)

(21) Appl. No.: 14/919,958

(22) Filed: Oct. 22, 2015

(30) Foreign Application Priority Data
Aug. 31, 2015 (CN) 201510545290.2

(51) Int. Cl. H01L 33/20; H01L 33/38; H01L 33/58; H01L 33/50; H01L 33/54; H01L 33/56

(52) U.S. Cl. CPC H01L 33/20; H01L 33/54; H01L 33/56; H01L 33/58; H01L 33/507; H01L 33/38

(57) ABSTRACT

The present disclosure provides a light emitting diode (LED) element which includes a semiconductor layer, a plurality of electrodes, a plurality of microstructures, and a first protecting layer. The semiconductor layer has a light outputting surface. The electrodes are formed on the semiconductor layer and located opposite to the light outputting surface. The microstructures are formed on the light outputting surface. The first protecting layer covers the light outputting surface and fills between the microstructures, and the first protecting layer is transparent.

### CROSS-REFERENCE TO RELATED APPLICATIONS

This application claims priority to Chinese patent application no. 201510545290.2, filed on Aug. 31, 2015, the contents of which are incorporated by reference herein.

### FIELD

The subject matter generally relates to light emitting diode (LED) element and particularly relates to an LED element having a protecting layer.

### BACKGROUND

Illumination devices can be based on one or more different light sources. For example, light sources can include incandescent light bulbs, compact fluorescent lamps and fluorescent tubes. Recent developments have made use of light emitting diodes. In some implementations, the illumination device can include a protecting layer in conduction with an LED element.

### BRIEF DESCRIPTION OF THE DRAWINGS

Implementations of the present technology will now be described, by way of example only, with reference to the attached figures.

FIG. 1 is a diagrammatic, cross-sectional view of an LED element in accordance with an exemplary embodiment of the present disclosure.

FIG. 2 is a diagrammatic, cross-sectional view of an LED element in accordance with an exemplary embodiment of the present disclosure.

FIG. 3 is a diagrammatic, cross-sectional view of an LED element in accordance with an exemplary embodiment of the present disclosure.

FIG. 4 is a diagrammatic, cross-sectional view of an LED element in accordance with an exemplary embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set fourth in order to provide a thorough understanding of the exemplary embodiments described herein. However, it will be understood by those of ordinary skill in the art that the exemplary embodiments described herein can be practiced without these specific details. In other instances, methods, procedures and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

A definition that applies throughout this disclosure will now be presented.

The term “comprising,” when utilized, means “including, but not necessarily limited to”; it specifically indicates open-ended inclusion or membership in the so-described combination, group, series and the like.

The present disclosure is described in relation to an LED having a reflecting cup.

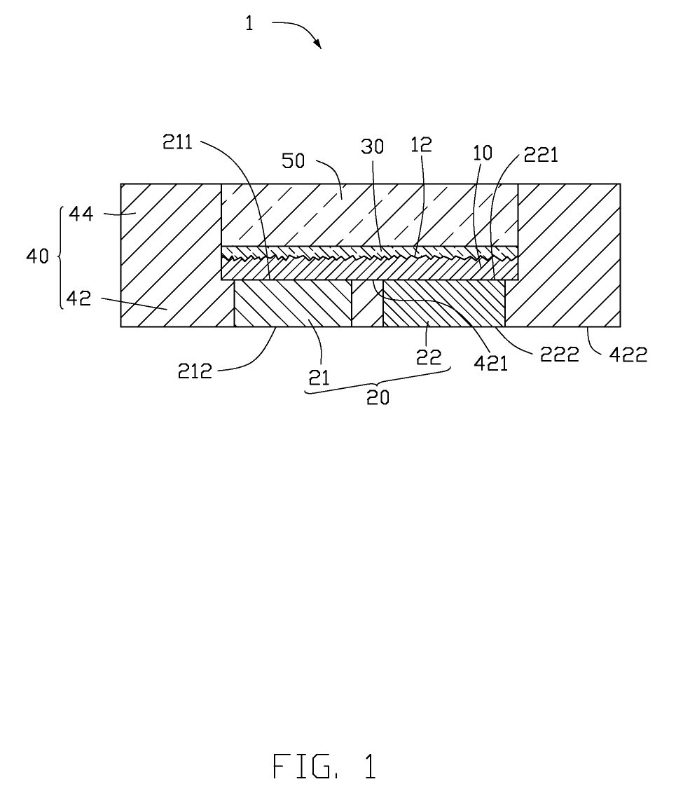

FIG. 1 illustrates an LED element 1 in accordance with a first exemplary embodiment of the present disclosure. The LED element 1 includes a semiconductor structure 10, a plurality of electrodes 20 formed on the semiconductor structure 10, and a first protecting layer 30 covering the semiconductor structure 10.

The semiconductor structure 10 can be a semiconductor layer of an LED die, which includes an N type semiconductor layer, an active layer and a P type semiconductor layer (not shown) that order. The semiconductor structure 10 can be grown on a substrate and the semiconductor structure 10 can be made by Metal-organic Chemical Vapor Deposition (MOCVD), Radio Frequency magnetron Sputter, Chemical Vaporous Depositon (CVD), Physical Vaporous Deposition (PVD), Atomic Layer Deposition (ALD), or Molecular Beam Epitaxy (MBE).

The semiconductor structure 10 includes a light outputting surface 12. The light outputting surface 12 has a plurality of microstructures 122 arranged thereon. The microstructures 122 are continuous spread on the light outputting surface 12.

The electrodes 20 include a first electrode 21 and a second electrode 22 spaced apart apart from the first electrode 21. The first electrode 21 and the second electrode 22 are made of metal having excellent electric capability, such as copper or aluminum. In the illustrated exemplary embodiment, the first electrode 21 and the second electrode 22 are located at a same side of the semiconductor structure 10. The first electrode 21 and the second electrode 22 are at an opposite side from the light outputting surface 12. Sides of the first electrode 21 and the second electrode 22 apart from the semiconductor structure 10 are exposed. Preferably, the first electrode 21 includes a first upper surface 211 and a first lower surface 212 opposite to the first upper surface 211, and the second electrode 22 includes a second upper surface 221 and a second lower surface 222 opposite to the second upper surface 221. The first upper surface 211 and the second upper surface 221 are attached onto the semiconductor structure 10, and the first lower surface 212 and the second lower surface 222 are exposed out of the LED element 1, for applying power for the LED element 1 via connecting to outer circuit (not show).

The first upper surface 211 of the first electrode 21 and the second upper surface 221 of the second electrode 22 can be coplanar. The first lower surface 212 of the first electrode 21 and the second lower surface 222 of the second electrode 22 can also be coplanar. In the illustrated exemplary embodiment, the first electrode 21, the second electrode 22 and the semiconductor structure 10 cooperate to form an LED die.

The first protecting layer 30 covers the semiconductor structure 10. In the illustrated exemplary embodiment, the first protecting layer 30 is directly attached on the light outputting surface 12 of the semiconductor structure 10 and fills the microstructures 122 to entirely cover the light outputting surface 12. The first protecting layer 30 is transparent. The first protecting layer 30 is made of organic material. The organic material can includes carbon, hydrogen, oxygen, and silicon.

The LED element 1 can further include a second protecting layer 40. The second protecting layer 40 packages the first electrode 21, the second electrode 22, and surrounds the semiconductor structure 10 and the first protecting layer 30. The second protecting layer 40 includes a bottom portion 42 and a side portion 44 extending upward from periphery edges of the bottom portion 42.

The bottom portion 42 engages the first electrode 21 and the second electrode 22 therein with the first lower surface 212 of the first electrode 21 and the second lower surface 222 of the second electrode 22 exposed out of the bottom portion 42. In other words, the bottom portion 42 includes a top surface 421 and a bottom surface 422 opposite to the top surface 421. The top surface 421 is coplanar to the first upper surface 211 of the first electrode 21 and the second upper surface 221 of the second electrode 22, and the bottom surface 422 is coplanar to the first lower surface 212 of the first electrode 21 and the second lower surface 222 of the second electrode 22. The Bottom portion 42 separates the first electrode 21 and the second electrode 22.

The side portion 44 surrounds the semiconductor structure 10 and the first protecting layer 30 therein. Inner surfaces of the side portion 44 are attached with outer surfaces of the semiconductor structure 10 and the first protecting layer 30.

The second protecting layer 40 can be non-transparent. The second protecting layer 40 can be made of organic material. The organic material can includes carbon, hydrogen, oxygen, and silicon.

When the LED element 1 works, heat generated from the semiconductor structure 10 directly transmits to the electrodes 20 and then dissipates out of the LED element 1. The first protecting layer 30 can directly protect the semiconductor structure 10 from dust or moisture to contact with the semiconductor structure 10. The second protecting layer 40 can further protect the semiconductor structure 10 from dust or moisture getting into the LED element 1.

The LED element 1 can also include a light guiding layer 50. The light guiding layer 50 covers the first protecting layer 30 and is surrounded by the second protecting layer 40 along with the first protecting layer 30. The light guiding layer 50 is formed on the first protecting layer 30 and is surrounded by the side portion 44 of the second protecting layer 40. The light guiding layer 50 can be made of transparent material, such as glass or sapphire. The light guiding layer 50 can adjust optical property of light emitted from the semiconductor structure 10. The light guiding layer 50 can further protect the semiconductor structure 10 from dust or moisture.

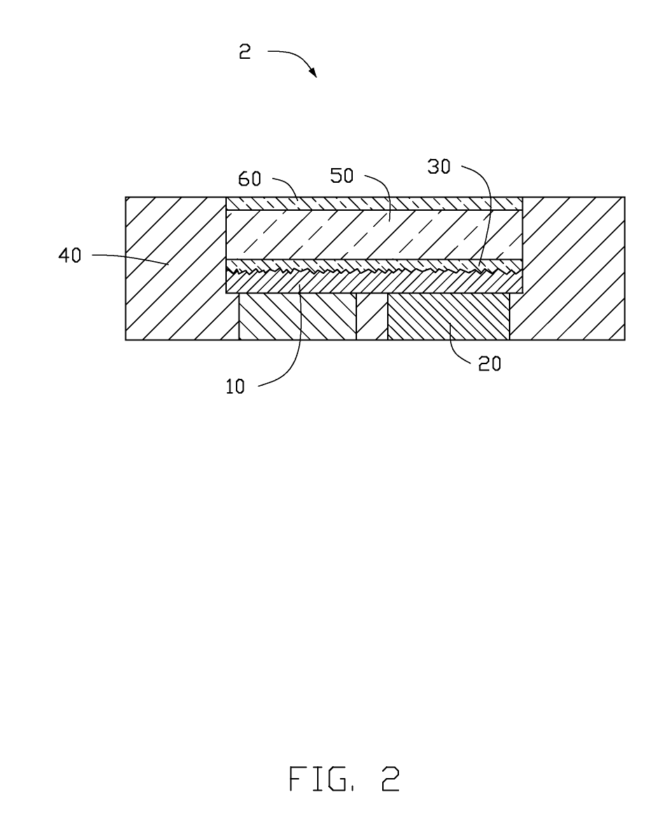

FIG. 2 illustrates an LED element 2 in accordance with a second exemplary embodiment of the present disclosure. The LED element 2 also includes an semiconductor structure 10, a plurality of electrodes 20 formed on the semiconductor structure 10, an first protecting layer 30 covering the semiconductor structure 10, a light guiding layer 50 covering the first protecting layer 30, and an second protecting layer 40 covering the electrodes 20 and surrounding the semiconductor structure 10, the first protecting layer 30 and the light guiding layer 50.

A difference between the LED element 2 of the second exemplary embodiment and the LED element 1 of the first exemplary embodiment is that a phosphor layer 60 is formed on the light guiding layer 50. The phosphor layer 60 has phosphor powder therein. In the illustrated exemplary embodiment, the semiconductor structure 10 emits blue light. The phosphor layer 60 has yellow phosphor powder therein. Thus, the LED element 2 emits white light when the blue light emitted from the semiconductor structure 10 penetrating through the phosphor layer 60.

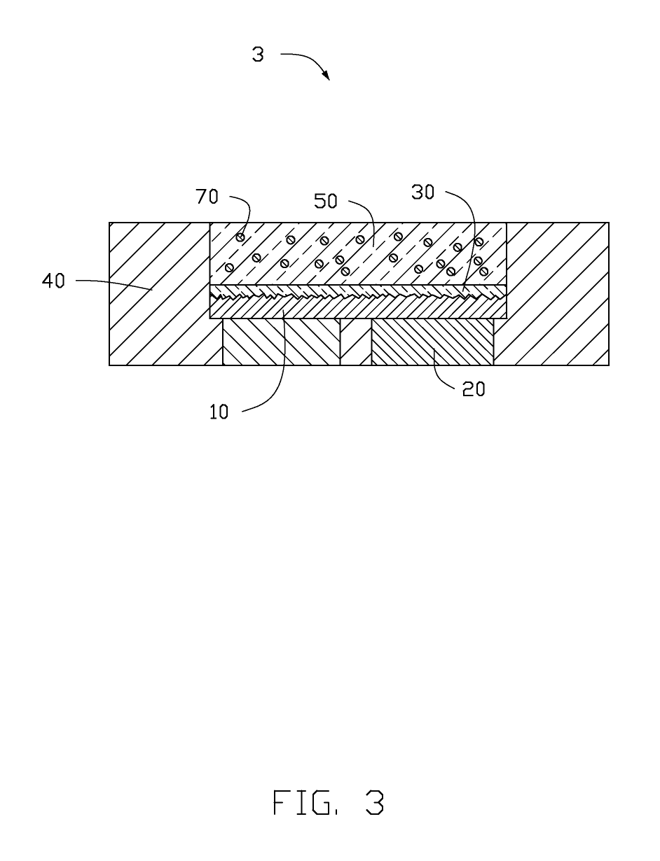

FIG. 3 illustrates an LED element 3 in accordance with a third exemplary embodiment of the present disclosure. The LED element 3 also includes an semiconductor structure 10, a plurality of electrodes 20 formed on the semiconductor structure 10, an first protecting layer 30 covering the semiconductor structure 10, a light guiding layer 50 covering the first protecting layer 30, and an second protecting layer 40 covering the electrode 20 and surrounding the semiconductor structure 10, the first protecting layer 30 and the light guiding layer 50.

A difference between the LED element 3 of the third exemplary embodiment and the LED element 1 of the first exemplary embodiment is that the light guiding layer 50 has phosphor powder therein. In the illustrated exemplary embodiment, the semiconductor structure 10 emits blue light. The light guiding layer 50 has yellow phosphor powder therein. Thus, the LED element 3 emits white light when the blue light emitted from the semiconductor structure 10 penetrating through the light guiding layer 50.

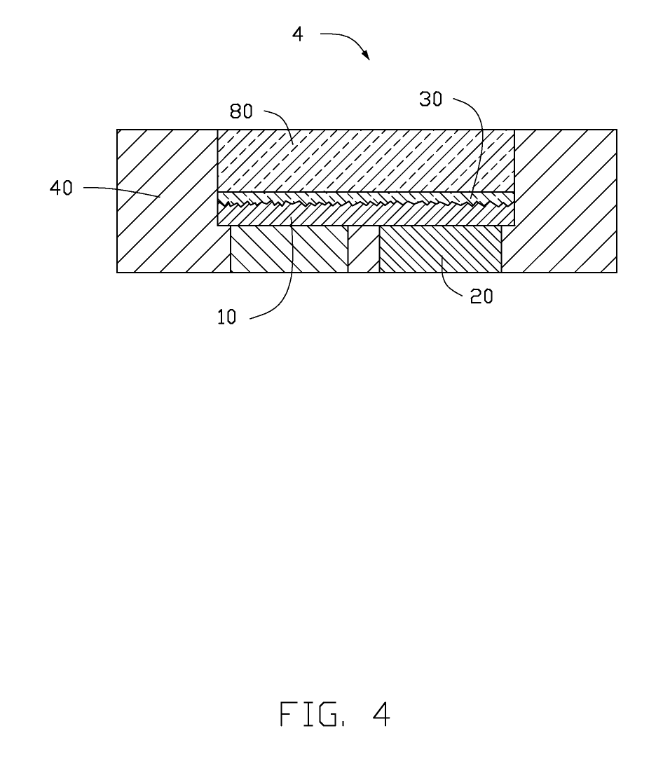

FIG. 4 illustrates an LED element 4 in accordance with a fourth exemplary embodiment of the present disclosure. The LED element 4 also includes a semiconductor structure 10, a plurality of electrode 20 formed on the semiconductor structure 10, an first protecting layer 30 covering the semiconductor structure 10, a light guiding layer 80 covering the first protecting layer 30, and an second protecting layer 40 covering the electrodes 20 and surrounding the semiconductor structure 10, the first protecting layer 30 and the light guiding layer 80.

A difference between the LED element 4 of the fourth exemplary embodiment and the LED element 1 of the first exemplary embodiment is that the light guiding layer 80 is made of Yttrium Aluminum Garnet (YAG) crystal.

It is to be further understood that even though numerous characteristics and advantages have been set forth in the foregoing description of exemplary embodiments, together with details of the structures and functions of the exemplary embodiments, the disclosure is illustrative only; and that changes may be made in detail, according in matters of shape, size, and arrangement of parts within the principles of the disclosure to the full extent indicated by the broad general meaning of the terms in which the appended claims are expressed.

The exemplary embodiments shown and described above are only examples. Many details are often found in the art such as the other features of the LED element. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the exemplary embodiments described above may be modified within the scope of the claims.

1. A light emitting diode (LED) element, comprising:
a semiconductor layer, the semiconductor layer comprising a light outputting surface;
a plurality of electrodes formed on the semiconductor layer and in direct contact with a surface of the semiconductor layer opposite to the light outputting surface, the electrodes exposing out from the LED element;
a plurality of microstructures formed on the light outputting surface; and
a first protecting layer, the first protecting layer covering the light outputting surface and encapsulating the microstructures, wherein the first protecting layer being transparent.

2. The LED element of claim 1, wherein the first protecting layer is made of organic material.

3. The LED element of claim 2, wherein the first protecting layer comprises carbon, hydrogen, oxygen, and silicon.

4. The LED element of claim 1, wherein a light guiding layer is covered on the first protecting layer, and wherein the light guiding layer is transparent.

5. The LED element of claim 4, wherein a phosphor layer is covered on the light guiding layer, and wherein the phosphor layer has phosphor powder therein.

6. The LED element of claim 4, wherein the light guiding layer has phosphor powder therein.

7. The LED element of claim 4, wherein the light guiding layer is made of Yttrium Aluminum Garnet (YAG) crystal.

8. The LED element of claim 1, further comprising a second protecting layer, wherein the second protecting layer packages the electrodes and surrounds the semiconductor layer and the first protecting layer.

9. The LED element of claim 8, wherein the second protecting layer is non-transparent.

10. The LED element of claim 8, wherein the second protecting layer comprises carbon, hydrogen, oxygen, and silicon.

11. The LED element of claim 8, wherein the second protecting layer comprises a bottom portion and a side portion extending upward from periphery edges of the bottom portion.

12. The LED element of claim 11, wherein the bottom portion engages the electrodes therein and separates the electrodes.

13. The LED element of claim 11, wherein the side portion surrounds the semiconductor layer and the first protecting layer therein.

14. The LED element of claim 11, wherein lower surfaces of the electrodes positioned opposite to the light outputting surface are exposed out of the bottom portion.

15. The LED element of claim 14, wherein the lower surfaces of the electrodes are coplanar to a bottom surface of the bottom portion, and wherein the upper surfaces of the electrodes positioned opposite to the lower surfaces are coplanar to a top surface of the bottom portion opposite to the bottom surface.

16. A light emitting diode (LED) element, comprising:
a semiconductor layer, the semiconductor layer comprising a light outputting surface;
a first electrode and a second electrode formed on the semiconductor layer and in direct contact with a surface of the semiconductor layer opposite to the light outputting surface, the first electrode and the second electrode exposing out from the LED element;
a plurality of microstructures formed on the light outputting surface;
a first protecting layer, the first protecting layer covering the light outputting surface and encapsulating the microstructures, wherein the first protecting layer being transparent; and
a second protecting layer, wherein the first electrode and second electrode are partially covered by the second protecting layer, and the first electrode and second electrode are separated from each other by the second protecting layer.

17. The LED element of claim 16, wherein the first protecting layer and the second protecting layer are both made of organic material, the first protecting layer and the second protecting layer comprises carbon, hydrogen, oxygen, and silicon.

18. The LED element of claim 16, wherein the second protecting layer packages the electrodes and surrounds both of the semiconductor layer and the first protecting layer, the second protecting layer comprises a bottom portion and a side portion extending upward from peripheral edges of the bottom portion, lower surfaces of the electrodes opposite to the light outputting surface are exposed out of the bottom portion, the lower surfaces of the electrodes are coplanar to a bottom surface of the bottom portion, and upper surfaces of the electrodes opposite to the lower surfaces are coplanar to a top surface of the bottom portion opposite to the bottom surface.

19. The LED element of claim 16, wherein a light guiding layer is covered on the first protecting layer, the light guiding layer is transparent, and the light guiding layer is surrounded by the second protecting layer.

20. The LED element of claim 19, wherein a phosphor layer is covered on the light guiding layer, the phosphor layer has phosphor powder therein, and the phosphor layer is surrounded by the second protecting layer.
